(19) United States
(12) Patent Application Publication
(10) Pub. No.: US 2021/0202294 A1
(43) Pub. Date: Jul. 1, 2021

(54) SUSCEPTOR

(71) Applicant: SHOWA DENKO K.K., Tokyo (JP)

(72) Inventors: Yuichiro MABUCHI, Saitama (JP); Yoshikazu UMETA, Saitama (JP)

(21) Appl. No.: 17/110,637

(22) Filed: Dec. 3, 2020

(30) Foreign Application Priority Data
Dec. 26, 2019 (JP) 2019-237349

(51) Int. Cl. H01L 21/687; C30B 25/12; C30B 29/36; C23C 16/32; C23C 16/458

(52) U.S. Cl. CPC H01L 21/6875; C30B 25/12; C23C 16/4586; C23C 16/325; C30B 29/36

(57) ABSTRACT

A susceptor for supporting a disk-shaped wafer when performing a surface treatment, includes a protruding region, and at least three support parts, provided on the protruding region, and configured to support the disk-shaped wafer by making contact with a back surface of the disk-shaped wafer. A ratio of a total area of the support parts with respect to an area of the protruding region is 10% or less in a plan view of the disk-shaped wafer.

### CROSS-REFERENCE TO RELATED APPLICATIONS

This application is based upon and claims priority to Japanese Patent Application No. 2019-237349 filed on Dec. 26, 2019, the entire contents of which are incorporated herein by reference.

### BACKGROUND OF THE INVENTION

### 1. Field of the Invention

The present invention relates to a susceptor.

### 2. Description of the Related Art

An epitaxial layer may be epitaxially grown on a disk-shaped wafer surface, such as a semiconductor wafer surface, for example. Conventionally, in a deposition process that forms the epitaxial layer, the disk-shaped wafer is heated in a state where the disk-shaped wafer is set on a susceptor provided inside a deposition apparatus.

When the disk-shaped wafer, which is flat, is set on the susceptor which is also flat, a gas may be sandwiched between the susceptor and the disk-shaped wafer, and cause a side slip of the disk-shaped wafer. In addition, when the disk-shaped wafer is deformed during the deposition process, the susceptor and the disk-shaped wafer may come into contact at unspecified locations. Such contact may generate particles from the disk-shaped wafer. The generated particles may inhibit the epitaxial growth. In addition, the generated particles may cause scratches or spot-like marks to form on a back surface of the disk-shaped wafer.

In order to prevent such inconveniences, Japanese Laid-Open Patent Publication No. 7-58039 proposes a susceptor having at least three support parts that support the disk-shaped wafer, such as the semiconductor wafer.

However, even when the proposed susceptor is used during the deposition process, the contact marks are formed on the back surface of the disk-shaped wafer after the epitaxial layer is epitaxially grown on the disk-shaped wafer. The contact marks affect subsequent processes, including a process performed with respect to the disk-shaped wafer, a focus alignment of a photolithography process, or the like, and may cause defects to be generated during such subsequent processes.

### SUMMARY OF THE INVENTION

One object of the embodiments of the present invention is to provide a susceptor that can prevent contact marks from being formed on a back surface of a disk-shaped wafer after a deposition process that forms an epitaxial layer.

A more specific object of the embodiments of the present invention is to provide a susceptor for supporting a disk-shaped wafer when performing a surface treatment, including a protruding region; and at least three support parts, provided on the protruding region, and configured to support the disk-shaped wafer by making contact with a back surface of the disk-shaped wafer, wherein a ratio of a total area of the support parts with respect to an area of the protruding region is 10% or less in a plan view of the disk-shaped wafer.

The support parts may be equally spaced to support an outer peripheral portion of the disk-shaped wafer at equally spaced positions, and the protruding region may have a ring shape along the outer peripheral portion of the disk-shaped wafer.

The protruding region may have a height in a range of 1 mm to 3 mm, and the support parts may have a height in a range of 0.1 mm to 2 mm.

The support parts may have a width in a range of 1 mm to 5 mm.

The susceptor may further include an upper surface having a wafer setting region where the disk-shaped wafer is set, wherein the protruding region has a ring shape protruding from the upper surface toward the disk-shaped wafer, inside the wafer setting region.

The support parts may have an upwardly convex spherical surface, a rectangular parallelepiped shape, or a cylindrical shape.

Other objects and further features of the present invention will be apparent from the following detailed description when read in conjunction with the accompanying drawings.

### BRIEF DESCRIPTION OF THE DRAWINGS

FIG. 1 is a plan view illustrating a susceptor according to a first embodiment viewed from above.

FIG. 2 is a cross sectional view illustrating the susceptor according to the first embodiment in a state where a disk-shaped wafer is set thereon.

FIG. 3 is a cross sectional view illustrating the susceptor according to a second embodiment in the state where the disk-shaped wafer is set thereon.

FIG. 4 is an optical microscope photograph of a contact portion on a back surface of the disk-shaped wafer according to an exemplary implementation.

FIG. 5 is an optical microscope photograph of a contact portion on the back surface of the disk-shaped wafer according to a comparative example.

### DESCRIPTION OF THE PREFERRED EMBODIMENTS

Embodiments of a susceptor according to the present invention will be described in detail with reference to the drawings. For the sake of convenience, some parts may be illustrated on an enlarged scale in the drawings to facilitate understanding thereof. For this reason, dimensional ratios of the various parts in the drawings may differ from the actual dimensional ratios of the various parts. In addition, the materials, the dimensions, or the like illustrated and described in the following are merely examples. Accordingly, the present invention is not limited to the following embodiments, and various variations, modifications, and substitutions may be made within a range that does not change requirements of the present invention.

<Susceptor>

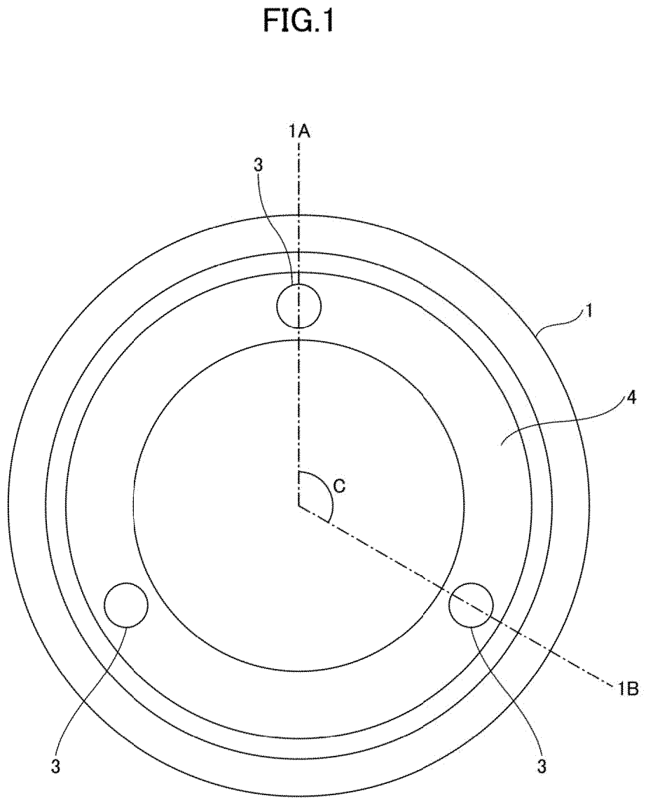

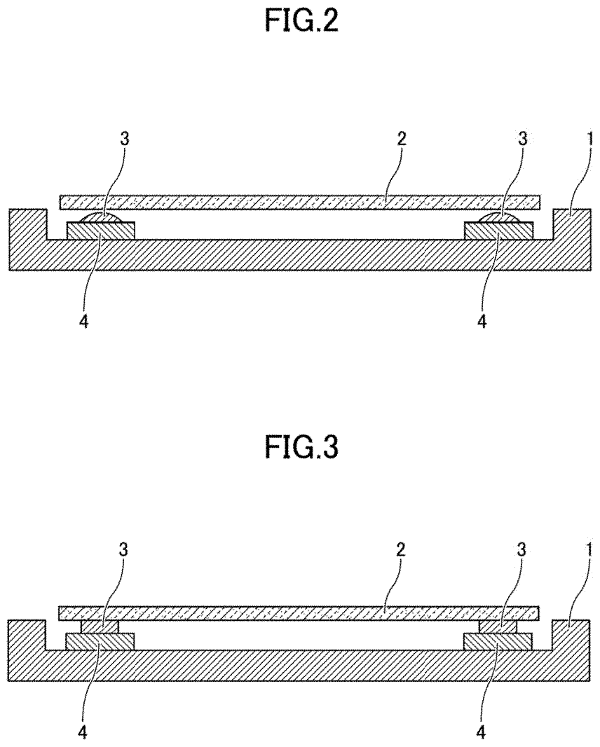

A susceptor according to a first embodiment will be described with reference to FIG. 1 and FIG. 2. The susceptor according to this embodiment is configured to support a disk-shaped wafer, such as a semiconductor wafer or the like, when performing a surface treatment, such as epitaxy, on the disk-shaped wafer. For example, the susceptor is used when manufacturing a SiC epitaxial wafer by setting a SiC substrate on the susceptor, and depositing a SiC epitaxial layer on the set SiC substrate.

FIG. 1 is a plan view illustrating the susceptor according to this viewed from above, in a vertical direction perpendicular with respect to a wafer surface. FIG. 2 is a cross sectional view illustrating the susceptor illustrated in FIG. 1 along a line 1A-1B, in a state where the disk-shaped wafer is set thereon.

A susceptor 1 according to this embodiment is provided inside a deposition apparatus (not illustrated), for example, and is used when performing a surface treatment or the like on a disk-shaped wafer 2. The susceptor 1 includes at least three support parts 3 that make contact with and support a back surface of the disk-shaped wafer 2. The support parts 3 are provided in a protruding region 4 of the susceptor 1. A ratio of a total area of the support parts 3 with respect to an area of the protruding region 4 is 10% or less in the plan view of the disk-shaped wafer 2. More particularly, the total area of the support parts 3 refers to a sum of the areas of the support parts 3, exposed on the protruding region 4 and making contact with the disk-shaped wafer 2 placed thereon, in the plan view of the disk-shaped wafer 2. Further, the area of the protruding region 4 refers to the entire area of the protruding region 4 exposed in the plan view of the disk-shaped wafer 2 in a state before the support parts 3 are provided on the protruding region 4.

In the example illustrated in FIG. 1 and FIG. 2, the support parts 3 have an upwardly convex spherical surface. However, the support parts 3 of the susceptor 1 may have a rectangular parallelepiped shape or a cylindrical shape, as illustrated in FIG. 3, for example. FIG. 3 is a cross sectional view illustrating the susceptor according to a second embodiment in the state where the disk-shaped wafer is set thereon. In FIG. 3, those parts that are the same as those corresponding parts in FIG. 1 and FIG. 2 are designated by the same reference numerals, and a description thereof will be omitted.

By using the susceptor 1 having the structure described above, it is possible to prevent contact marks from being formed on the back surface of the disk-shaped wafer 2 after the SiC epitaxial layer is epitaxially grown on the disk-shaped wafer 2, and maintain the back surface of the disk-shaped wafer 2 in an excellent state.

For example, when a susceptor having a conventional structure is used to deposit the SiC epitaxial layer on the wafer surface, contact marks may be formed on the back surface of the disk-shaped wafer. It may be regarded that the contact marks are formed on the back surface of the disk-shaped wafer due to heat transfer from the support parts of the susceptor, that causes local heating of the disk-shaped wafer, which in turn causes local sublimation of the disk-shaped wafer.

On the other hand, the support parts 3 of the susceptor 1 according to this embodiment are provided on the protruding region 4. For this reason, in addition to receiving the heat transfer from the support parts 3, the back surface of the disk-shaped wafer 2 is heated by radiation heat from the protruding region 4. In other words, the back surface of the disk-shaped wafer 2, near contact portions making contact with the support parts 3, is also heated by the radiation heat from the protruding region 4. Further, since the ratio of the total area of the support parts 3 with respect to the area of the protruding region 4 is 10% or less in the plan view of the disk-shaped wafer 2 and small, a temperature gradient of the contact portion becomes gradual, and the local sublimation at the back surface of the disk-shaped wafer 2 becomes gradual. Accordingly, it is possible to maintain the back surface of the disk-shaped wafer 2 in an excellent state.

In the susceptor 1 according to this embodiment, the ratio of the area of the protruding region 4 with respect to the total area of the back surface of the disk-shaped wafer 2 is preferably within a range of 5% to 30% in the plan view of the disk-shaped wafer 2. By using the susceptor 1 having such a structure, it is possible to prevent contact marks from being formed on the back surface of the disk-shaped wafer 2 after the SiC epitaxial layer is epitaxially grown on the disk-shaped wafer 2, and maintain the back surface of the disk-shaped wafer 2 in the excellent state.

In the susceptor 1 according to this embodiment, the positions where the support parts 3 are provided on an upper surface of the susceptor 1 are not particularly limited, as long as the positions of the support parts 3 enable the disk-shaped wafer 2 to be supported thereby. However, as illustrated in FIG. 1, the support parts 3 preferably support an outer peripheral portion of the disk-shaped wafer 2 at equally spaced positions, and the protruding region 4 is preferably provided in a ring shape (or annular shape) along the outer peripheral portion of the disk-shaped wafer 2. In FIG. 1, the three support parts 3 are provided at equally spaced positions having an angular separation of 120 degrees with respect to a center of the susceptor 1. However, the disk-shaped wafer 2 may be supported more stably by the susceptor 1 by providing more than three support parts 3.

By using the susceptor 1 having such a structure, it is possible to stably support the disk-shaped wafer 2, prevent contact marks from being formed on the back surface of the disk-shaped wafer 2 after the epitaxial layer is epitaxially grown on the disk-shaped wafer 2, and maintain the back surface of the disk-shaped wafer 2 in the excellent state.

In other words, the susceptor 1 according to this embodiment includes the protruding region 4, that has the ring shape protruding from the upper surface of the susceptor 1 toward the disk-shaped wafer 2, inside a wafer setting region of the susceptor 1 where the disk-shaped wafer 2 is set. In the plan view, the protruding region 4 is located on an inner side of an outer edge of the wafer setting region of the susceptor 1, and protrudes upward in FIG. 2 or FIG. 3. Furthermore, the three support parts 3 are arranged at equally spaced positions on the protruding region 4, and protrude upward toward the disk-shaped wafer 2 in FIG. 2 and FIG. 3. The disk-shaped wafer 2 is set on the three support parts 3 provided on the protruding region 4 of the susceptor 1.

When the disk-shaped wafer 2 having a standard 3-inch diameter to a standard 6-inch diameter is to be set on the susceptor 1 according to this embodiment, the protruding region 4 preferably has a height within a range of 1 mm to 3 mm, and the support parts 3 preferably have a height within a range of 0.1 mm to 2 mm.

By using the susceptor 1 having such a structure, it is possible to prevent contact marks from being formed on the back surface of the disk-shaped wafer 2 after the SiC epitaxial layer is epitaxially grown on the disk-shaped wafer 2, and maintain the back surface of the disk-shaped wafer 2 in the excellent state.

When the protruding region 4 having the ring shape illustrated in FIG. 1 is used in the susceptor 1 according to this embodiment, the protruding region 4 preferably has a width within a range of 1 mm to 5 mm. In FIG. 1, the protruding region 4 has a continuous ring shape. However, the protruding region 4 may have an intermittent (or discontinuous) ring shape formed by ring segments (or ring portions). In this case, each support part 3 may be provided on one or more ring segments.

By using the susceptor 1 having such a structure, it is possible to prevent contact marks from being formed on the back surface of the disk-shaped wafer 2 after the SiC epitaxial layer is epitaxially grown on the disk-shaped wafer 2, and maintain the back surface of the disk-shaped wafer 2 in the excellent state.

The susceptor 1 according to this embodiment may be suitably applied to the epitaxial growth using the SiC wafer with a growth rate of 2 μm/h to 100 μm/h, at a growth temperature in a range of 1000° C. to 1800° C., and a decompression atmosphere of 300 Torr or lower.

### Exemplary Implementation

In an exemplary implementation, a disk-shaped susceptor having a diameter of 110 mm, such as that illustrated in FIG. 1 or FIG. 2, was provided inside the deposition apparatus. A protruding region having a ring shape, with an outer diameter of 100 mm, an inner diameter of 98 mm, and a height of 2.5 mm, was provided on the upper surface of the susceptor inside the wafer setting region. In addition, three support parts having a square shape, such as that illustrated in FIG. 3, with each side of 2 mm, and a height of 0.3 mm, were provided on the protruding region at equally spaced positions having an angular separation of 120 degrees with respect to the center of the susceptor.

A SiC wafer having a diameter of 100 mm, was set on the above described susceptor, as the disk-shaped wafer, and an epitaxial layer was epitaxially grown on the SiC wafer by a deposition process.

The epitaxial layer was epitaxially grown for 0.5 hours by the deposition process, while supplying a silane-based gas and a propane gas as source gases.

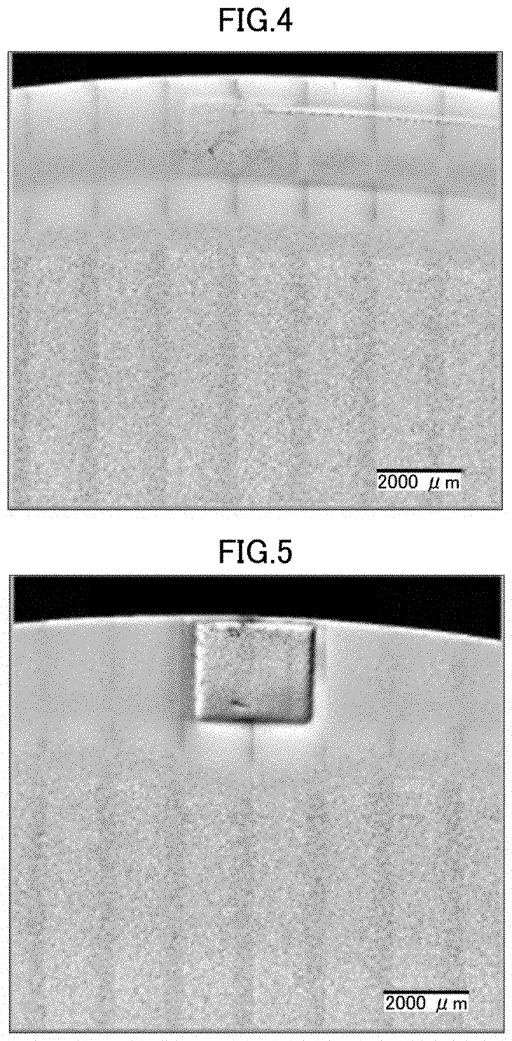

After the deposition process, the SiC wafer was removed from the susceptor, to observe the back surface of the SiC wafer. The amount of sublimation at the contact portions of the back surface of the SiC wafer, making contact with the support parts, was less than 10 μm. FIG. 4 is an optical microscope photograph of the contact portion on the back surface of the SiC wafer according to the exemplary implementation.

### Comparative Example

An outline of a susceptor according to a comparative example is the same as that of the exemplary implementation described above, however, no protruding region having the ring shape is provided on the upper surface of the susceptor inside the wafer setting region, and the support parts similar to those of the exemplary implementation are provided directly on the upper surface of the susceptor. Otherwise, the susceptor according to the comparative example is similar to that of the exemplary implementation, and an epitaxial layer was epitaxially grown on the SiC wafer by a deposition process under conditions similar to those of the exemplary implementation.

After the deposition process, the SiC wafer was removed from the susceptor, to observe the back surface of the SiC wafer. The amount of sublimation at the contact portions of the back surface of the SiC wafer, making contact with the support parts, was 10 μm. FIG. 5 is an optical microscope photograph of the contact portion on the back surface of the SiC wafer according to the comparative example.

It was confirmed from the optical microscope photographs that the contact mark remained on the back surface of the SiC wafer in the comparative example illustrated in FIG. 5, whereas no contact mark remained on the back surface of the SiC wafer in the exemplary implementation illustrated in FIG. 4.

According to the present disclosure, it is possible to provide a susceptor that can prevent contact marks from being formed on a back surface of a disk-shaped wafer after a deposition process that forms an epitaxial layer, and maintain the back surface of the disk-shaped wafer in an excellent state.

Although the embodiments are numbered with, for example, “first,” or “second,” the ordinal numbers do not imply priorities of the embodiments.

Further, the present invention is not limited to these embodiments and exemplary implementations, but various variations, modifications, and substitutions may be made without departing from the scope of the present invention.

What is claimed is:

1. A susceptor for supporting a disk-shaped wafer when performing a surface treatment, comprising:
a protruding region; and
at least three support parts, provided on the protruding region, and configured to support the disk-shaped wafer by making contact with a back surface of the disk-shaped wafer,
wherein a ratio of a total area of the support parts with respect to an area of the protruding region is 10% or less in a plan view of the disk-shaped wafer.

2. The susceptor as claimed in claim 1, wherein
the support parts are equally spaced to support an outer peripheral portion of the disk-shaped wafer at equally spaced positions, and
the protruding region has a ring shape along the outer peripheral portion of the disk-shaped wafer.

3. The susceptor as claimed in claim 2, wherein the protruding region has a height in a range of 1 mm to 3 mm, and the support parts have a height in a range of 0.1 mm to 2 mm.

4. The susceptor as claimed in claim 1, wherein the protruding region has a height in a range of 1 mm to 3 mm, and the support parts have a height in a range of 0.1 mm to 2 mm.

5. The susceptor as claimed in claim 3, wherein the support parts have a width in a range of 1 mm to 5 mm.

6. The susceptor as claimed in claim 4, wherein the support parts have a width in a range of 1 mm to 5 mm.

7. The susceptor as claimed in claim 1, wherein the support parts have a width in a range of 1 mm to 5 mm.

8. The susceptor as claimed in claim 1, further comprising:
an upper surface having a wafer setting region where the disk-shaped wafer is set,
wherein the protruding region has a ring shape protruding from the upper surface toward the disk-shaped wafer, inside the wafer setting region.

9. The susceptor as claimed in claim 8, wherein the support parts have an upwardly convex spherical surface.

10. The susceptor as claimed in claim 8,
wherein the support parts have a rectangular parallelepiped shape or a cylindrical shape.
